(19) United States
(12) Patent Application Publication
(10) Pub. No.: US 2018/0166301 A1
(43) Pub. Date: Jun. 14, 2018

(54) SEMICONDUCTOR MANUFACTURING SYSTEM

(71) Applicant: TAIWAN SEMICONDUCTOR MANUFACTURING CO., LTD., Hsinchu (TW)

(72) Inventors: Yu-Lung Chang, Taichung City (TW); Hsiang-Ruei He, Taichung (TW); Sheng-Hung Lin, Taichung City (TW)

(21) Appl. No.: 15/471,258

(22) Filed: Mar. 28, 2017

Related U.S. Application Data
(60) Provisional application No. 62/433,310, filed on Dec. 13, 2016.

(51) Int. Cl. H01L 21/67; H01L 21/3065; H01J 37/32

(52) U.S. Cl. CPC H01L 21/67069; H01L 21/3065; H01J 2237/334; H01J 37/32926; H01J 37/32082

(57) ABSTRACT

A system includes a protection device and a blocking device. The protection device is installed on a wall of a chamber. The protection device is configured to protect the wall of the chamber from plasma associated with a semiconductor manufacturing process that is performed by a tool. The blocking device is arranged between the protection device and the wall to block up a gap therebetween.

### RELATED APPLICATIONS

This application claims priority to U.S. Provisional Application Ser. No. 62/433,310, filed Dec. 13, 2016, which is herein incorporated by reference.

### BACKGROUND

In semiconductor manufacturing processes, etching is configured to remove a specific layer from a semiconductor body. To achieve better etching results, the etching process should be stopped being performed on the semiconductor body when the specific layer is removed from the semiconductor body. In some approaches, an endpoint detection (EPD) system is employed to determine when to stop performing the etching process. With the arrangement of the EPD system, a timing point at which the specific layer is fully removed is able to be determined, and thus the better results are obtained.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram illustrating a system, in accordance with some embodiments of the present disclosure;

FIG. 2 is a schematic diagram illustrating a chamber, a light receiving device, and a sensor of the system in FIG. 1, in accordance with some embodiments of the present disclosure;

FIG. 3 is a schematic diagram illustrating a cross section associated with a line in FIG. 2, in accordance with some embodiments of the present disclosure ;

FIG. 4 is a flow chart of a method illustrating operations of the system in FIG. 1, in accordance with some embodiments of the present disclosure; and

FIG. 5 is a schematic diagram illustrating the chamber of the system in FIG. 1, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the some embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to some embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

The terms “comprise,” “comprising,” “include,” “including,” “has,” “having,” etc. used in this specification are open-ended and mean “comprises but not limited.”

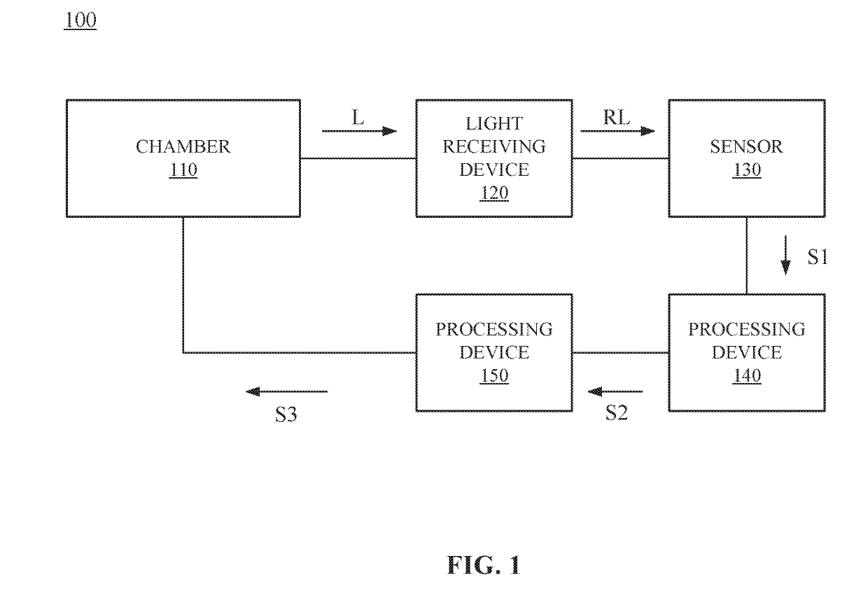

Reference is now made to FIG. 1. FIG. 1 is a schematic diagram illustrating a system 100, in accordance with some embodiments of the present disclosure. In some embodiments, the system 100 is applied in an endpoint detection (EPD) system.

For illustration, the system 100 includes a chamber 110, a light receiving device 120, a sensor 130, a processing device 140, and a processing device 150.

As illustratively shown in FIG. 1, the light receiving device 120 is coupled to the chamber 110 and the sensor 130. The chamber 110 is arranged as a room at which a semiconductor manufacturing process is performed. The processing device 140 is coupled to the sensor 130 and the processing device 150. The processing device 150 is coupled to the chamber 110. Effectively, the system 100 operates as a feedback mechanism, in order to control and monitor the semiconductor manufacturing process performed in the chamber 110.

The above discussion merely describes exemplary connections that can be made in accordance with various alternative embodiments. It is understood that such various alternative embodiments are not limited to the specific connections described above or those shown in FIG. 1.

In addition, in this document, the term “coupled” may also be termed as “electrically coupled,” and the term “connected” may be termed as “electrically connected.” “Coupled” and “connected” may also be used to indicate that two or more elements cooperate or interact with each other.

In some embodiments, the semiconductor process performed in the chamber 110 includes an etching process. The etching process is performed to remove a specific layer or a specific material from a semiconductor body. The type of the semiconductor process is given for illustrative purposes only. Various types of semiconductor process are within the contemplated scope of the present disclosure.

In some embodiments, the semiconductor body includes, for example, a wafer, a substrate, or similar components. The type of the semiconductor body is given for illustrative purposes only. Various types of semiconductor body are within the contemplated scope of the present disclosure.

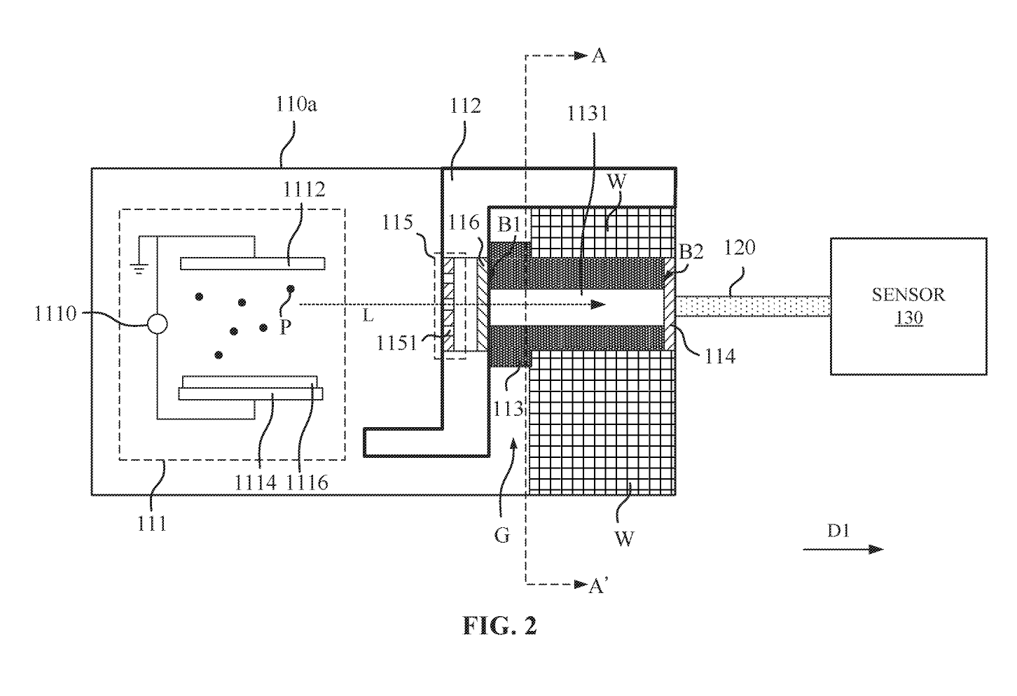

In some embodiments, when the etching process is performed in the chamber 110, plasma (labeled with a reference number P in FIG. 2 below), light L, and some byproducts (not shown) are generated in the chamber 110. The plasma P is configured to etch the specific layer or the specific material from the semiconductor body. During the specific layer or the specific material is etched, the light L is correspondingly generated. In some embodiments, a light spectrum of the light L is associated with the specific layer or the specific material which is etched.

For illustration, the light receiving device 120 is configured to receive and guide the light L, to output light RL to the sensor 130. In some embodiments, the light receiving device 120 is implemented with one or more optical fibers. In some embodiments, the light RL is substantially equal to the light L. In some other embodiments, an intensity of the light RL is smaller than an intensity of the light L.

The implementation of the light receiving device 120 is given for illustrative purposes only. Various implementations of the light receiving device 120 are within the contemplated scope of the present disclosure.

In some embodiments, the sensor 130 is configured to generate spectrum information S1 according to the light RL from the light receiving device 120. In some embodiments, the sensor 130 includes a monochromator (not shown), a detector (not shown), and an amplifier (not shown). The monochromator receives the light RL from the light receiving device 120. The monochromator then splits the wavelength of the light RL into different wavelengths. The detector detects the split light from the monochromator, and converts the same to an electrical signal. Then, the amplifier amplifies the electrical signal and outputs the amplified electrical signal as the spectrum information S1.

The configurations of the sensor 130 are given for illustrative purposes only. Various configurations of the sensor 130 are within the contemplated scope of the present disclosure.

In some embodiments, the processing device 140 is configured to receive and process the spectrum information S1, to generate analyzed information S2. In some embodiments, the processing device 140 processes the spectrum information S1 by using a diagram, which shows relationships between signal intensities and time, in order to generate the analyzed information S2. In some embodiments, the analyzed information S2 includes data associated with the diagram.

As described above, the system 100 may be applied to the EPD system in some embodiments. In some embodiments, the EPD system is configured to determine when to stop the etching process based on at least one signal associated with the etching process. In some embodiments, the at least one signal includes the light RL, the spectrum information S1, and/or the analyzed information S2. In other words, the EPD system is configured to determine a timing point at which the specific layer or the specific material is etched to have a predetermined thickness. In some embodiments, the timing point is referred to as “endpoint time.” The EPD system is further configured to stop the etching process according to the endpoint time, in order to prevent the semiconductor body from being further etched.

In some embodiments, the processing device 150 is configured to control a tool (labeled with a reference number 111 in FIG. 2 below) in the chamber 110 according to the analyzed information S2. In some embodiments, the tool 111 is configured to perform the etching process. The processing device 150 determines the endpoint time of the etching process according to the analyzed information S2. When the endpoint time is determined, the processing device 150 generates a control signal S3 to control the tool 111 to stop the etching process. As a result, the semiconductor body is prevented from being etched.

In some embodiments, the processing device 140 or the processing device 150 is implemented with a computer. In some other embodiments, the processing device 140 or the processing device 150 is, for example, a central processing unit (CPU), an application specific integrated circuit (ASIC), a multi-processor, a distributed processing system, or a suitable processing unit.

The implementations of the processing device 140 and the processing device 150 are given for illustrative purposes only. Various implementations of the processing device 140 and the processing device 150 are within the contemplated scope of the present disclosure. For example, in some other embodiments, the processing device 140 and the processing device 150 are integrated into one processing device.

The above configurations of the system 100 are given for illustrative purposes only. Various configurations of the system 100 are within the contemplated scope of the present disclosure.

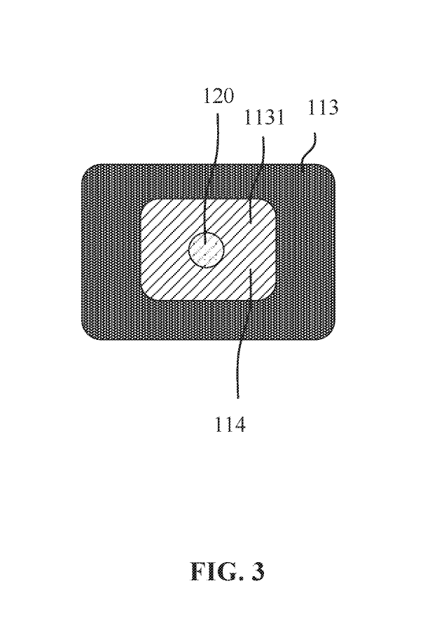

Reference is now made to FIG. 2 and FIG. 3. FIG. 2 is a schematic diagram illustrating the chamber 110, the light receiving device 120, and the sensor 130 of the system 100 in FIG. 1, in accordance with some embodiments of the present disclosure. In some embodiments, the chamber 110 in FIG. 1 is arranged as a chamber 110a in FIG. 2. FIG. 3 is a schematic diagram illustrating a cross section associated with a line AA′ in FIG. 2, in accordance with some embodiments of the present disclosure. For ease of understanding, with respect to the embodiments of FIG. 1, like elements in FIG. 2 or FIG. 3 are designated with the same reference numbers.

In some embodiments, the chamber 110a includes one or more side walls. For ease of understanding, only one side wall W of the chamber 110a is explicitly illustrated in FIG. 2. Other side walls are represented by lines. The side wall W is, for example, a back wall of the chamber 110a. In some embodiments, the chamber 110a further includes a top cover and a bottom cover. The top cover, the bottom cover, and the side walls form a closed room. In some embodiments, during the etching process is performed in the closed room, the closed room is controlled to be a vacuum environment.

For illustration, the chamber 110a includes a tool 111. In some embodiments, the tool 111 is configured to perform a semiconductor process, which includes, for example, the etching process as discussed above. As illustratively shown in FIG. 2, the tool 111 includes a radio frequency (RF) generator 1110, a top electrode plate 1112, and a bottom electrode plate 1114.

In some embodiments, if the etching process is performed for removing the specific layer or the specific material on a wafer 1116, the wafer 1116 is disposed above the bottom electrode plate 1114, and etching gas is injected into the chamber 110a during the etching process. Then, the RF generator 1110 is controlled, by the processing device 150, to be turned on. When the RF generator 1110 is turned on, the etching gas is converted into the plasma P.

In some embodiments, the system 100 includes a protection device 112 and a blocking device 113. The protection device 112 is configured to be installed on the side wall W and is removable. When the protection device 112 is installed on the side wall W, the protection device 112 shields the side wall W and protects the side wall W from the plasma P. Explained in a different way, the plasma P hits the protection device 112 instead of the side wall W. Accordingly, the contact between the plasma P and the side wall W is avoided. As a result, a lifetime of the chamber 110a can be extended.

In some embodiments, the system 100 further includes a window 114. The window 114 is referred to as a viewing window. The window 114 is configured to be installed on the side wall W. The light receiving device 120 is arranged at a side of the window 114 to receive the light L via the window 114. In some embodiments, the window 114 is formed of quartz. The light L is transmitted from the tool 111, via the window 114, to the light receiving device 120.

The implementation of the window 114 is given for illustrative purposes. Various transparent materials to form the window 114 are within the contemplated scope of the present disclosure.

As illustratively shown in FIG. 2, when the protection device 112 is installed on the side wall W, a gap G is formed between the protection device 112 and the side wall W. In some embodiments, the byproducts introduced from the etching process are, by some possibility, deposited on the window 114 via the gap G. The byproducts are, for example, polymers, but the present disclosure is not limited thereto. For example, if the specific layer or the specific material on the wafer 1116 includes nitride (N), polymer is generated by a mixing of nitride, carbon (C), and fluorine (F). Carbon and fluorine are from the etching gas. In some embodiments, the byproducts discussed above are colored. For example, the byproducts are white or other colors. If the byproducts are deposited on the window 114, a transmittance of the window 114 is decreased. As a result, the intensity of the light L received by the light receiving device 120 decreases.

For illustration, the blocking device 113 is arranged between the protection device 112 and the side wall W, in order to block up the gap G. As the gap G is blocked up, the only way at which the byproducts can pass through to the window 114 is blocked. Accordingly, the byproducts can be prevented from being deposited on the window 114 by the blocking device 113. As a result, the transmittance of the window 114 can be maintained for a long time and time for cleaning the window 114 can be saved.

In some embodiments, the blocking device 113 is formed of polytetrafluoroethylene (PTFE). In some embodiments, a through-hole 1131 is formed on the blocking device 113. In some embodiments, a central axis of the through-hole 1131 is in a direction D1. In some embodiments, the light receiving device 120 is aligned in the direction D1. In other words, in some embodiments, the light receiving device 120 is aligned with the central axis of the through-hole 1131, as illustratively shown in FIG. 3. Effectively, the through-hole 1131 is configured to operate as a guiding channel for guiding the light L from the tool 111 to the window 114.

In some embodiments, the system 100 further includes a filtering device 115 and a window 116. The filtering device 115 and the window 116 are configured to be installed on the protection device 112. The filtering device 115 is, for example, a Y-coating window. In some embodiments, the window 116 is formed of sapphire thereto. The implementations of the filtering device 115 and the window 116 are given for illustrative purposes only. Various implementations of the filtering device 115 and the window 116 are within the contemplated scope of the present disclosure.

As illustratively shown in FIG. 2, the filtering device 115 is disposed at a first side of the protection device 112, and the window 116 is disposed at a second side of the protection device 112. The first side of the protection device 112 faces to the tool 111, and the second side of the protection device 112 faces to a side B1 of the blocking device 113. In addition, the window 114 is disposed at a side B2 of the blocking device 113. The side B2 is opposite to the side B1 and faces to the light receiving device 120. In other words, the blocking device 113 is arranged between the window 116 and the window 114.

The filtering device 115 is configured to filter most of the plasma P. For illustration, holes 1151 are formed on the filtering device 115. When the etching process is performed by the tool 111, most of the plasma P is blocked by the filtering device 115. The light L and the remaining amount of the plasma P are transmitted through the holes 1151 of the filtering device 115. The transmitted light L is then transmitted through the window 116 and the transmitted plasma P is blocked by the window 116. Effectively, the protection device 112 and the window 116 protect the side wall W and the window 114 from being contacted by the plasma P.

As a result, the light L is transmitted from the tool 111, through the holes 1151 of the filtering device 115, to the window 116. The light L is then transmitted through the through-hole 1131 of the blocking device 113 to the window 114. Thus, the light receiving device 120 receives the light L via the window 114.

As mentioned above, the transmittance of the window 114 is maintained by the blocking device 113, and the intensity of the light L received by the light receiving device 120 is thus kept. Thus, the processing device 150 is able to precisely control the etching process according to the light L.

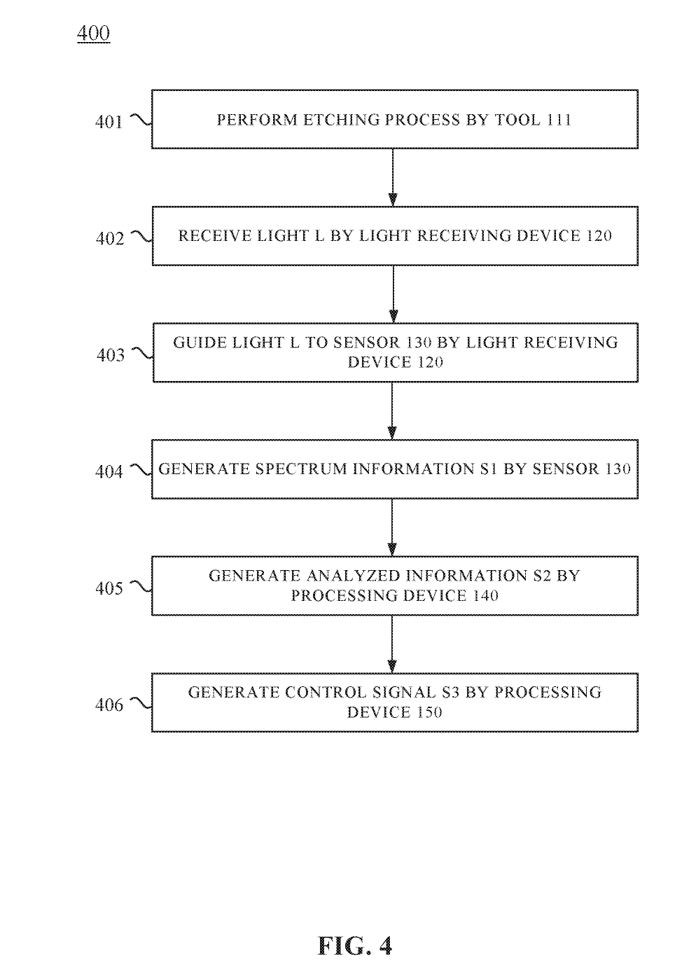

Reference is now made to FIG. 4. FIG. 4 is a flow chart of a method 400 illustrating operations of the system 100 in FIG. 1, in accordance with some embodiments of the present disclosure. For illustration, the method 400 includes operations 401-406. For ease of understanding of the present disclosure, the method 400 is discussed in relation to FIG. 1 and FIG. 2, but the present disclosure is not limited thereto.

In operation 401, the tool 111 in the chamber 110a performs the etching process. As described above, during the etching process is performed, the etching gas is injected into the chamber 110a, and the RF generator 1110 is turned on. Thus, the injected etching gas is converted to the plasma P, in order to etch the specific layer or the specific material on the wafer 1116. When the specific layer or the specific material is etched, the light L is generated. In some embodiments, the wavelengths of the light L are associated with the etched material. For example, when a different material is etched, the wavelengths of the light L would be different.

In operation 402, the light receiving device 120 receives the light L via the window 114. In some embodiments, the light L is transmitted from the tool 111, passing through the holes 1151 of the filtering device 115, to the window 116. Then, the light L is guided from the window 116, by the through-hole 1131 of the blocking device 113, to the window 114. In some embodiments, a first terminal of the light receiving device 120 is coupled to window 114, in order to receive the light L via the window 114.

In operation 403, the light receiving device 120 guides the light L to the sensor 130. In some embodiments, the light receiving device 120 guides the light L from the first terminal of the light receiving device 120 to a second terminal of the light receiving device 120. The second terminal is coupled to the sensor 130, in order to output the light RL to the sensor 130.

In operation 404, the sensor 130 generates spectrum information S1 according to the light RL from the light receiving device 120. As discussed above, the sensor 130 detects the light RL from the light receiving device 120 and splits the wavelength of the light RL into different wavelengths. The sensor 130 then generates spectrum information S1 according to the different wavelengths and their corresponding intensities. In other words, in some embodiments, the spectrum information S1 includes relationships between the wavelengths of the light RL and the corresponding intensities.

In operation 405, the processing device 140 generates the analyzed information S2 according to the spectrum information S1. In some embodiments, the processing device 140 converts the spectrum information S1 into a diagram. The diagram shows relationships between signal intensities and time. Data indicating the diagram is included in the analyzed information S2. The analyzed information S2 is then output by the processing device 140. In some embodiments, a signal intensity in the diagram is corresponding to a thickness of the specific layer on the wafer 1116. For example, when the etching process is just started, the signal intensity corresponding to the specific layer is strong. Under this condition, the thickness of the specific layer is indicated, by the strong signal intensity, to be thicker. After a period of time, the signal intensity corresponding to the specific layer becomes weaker. It represents that the thickness of the specific layer becomes thinner. Effectively, the signal intensity corresponding to the specific layer is sufficient to indicate the progress of the etching process.

In operation 406, the processing device 150 generates the control signal S3 according to the analyzed information S2. In some embodiments, the processing device 150 receives the analyzed information S2, and determines the endpoint time corresponding to the specific layer according to the analyzed information S2. For example, when the signal intensity corresponding to the specific layer is substantially equal to 0, it represents that the thickness of the specific layer is substantially equal to 0. Under this condition, the processing device 150 determines that the endpoint time corresponding to the specific layer is up. When the endpoint time corresponding to the specific layer is up, the processing device 150 outputs the control signal S3 to the tool 111, in order to control the tool 111 to stop the etching process. For example, the RF generator 1110 of the tool 111 is controlled, by the control signal S3, to be turned off. When the RF generator 1110 is turned off, the etching gas is stopped from being converted into the plasma P. As a result, the etching process is stopped and the wafer 1116 is prevented from being further etched.

As mentioned above, the byproducts are prevented from being depositing on the window 114 by the block device 113. Thus, the intensity of the light L transmitted via the window 114 can be kept. As a result, the processing device 150 is able to precisely turn off the RF generator 1110, in order to stop the etching process.

The above description of the method 400 includes exemplary operations, but the operations of the method 400 are not necessarily performed in the order described. The order of the operations of the method 400 disclosed in the present disclosure is able to be changed, or the operations are able to be executed simultaneously or partially simultaneously as appropriate, in accordance with the spirit and scope of some embodiments of the present disclosure.

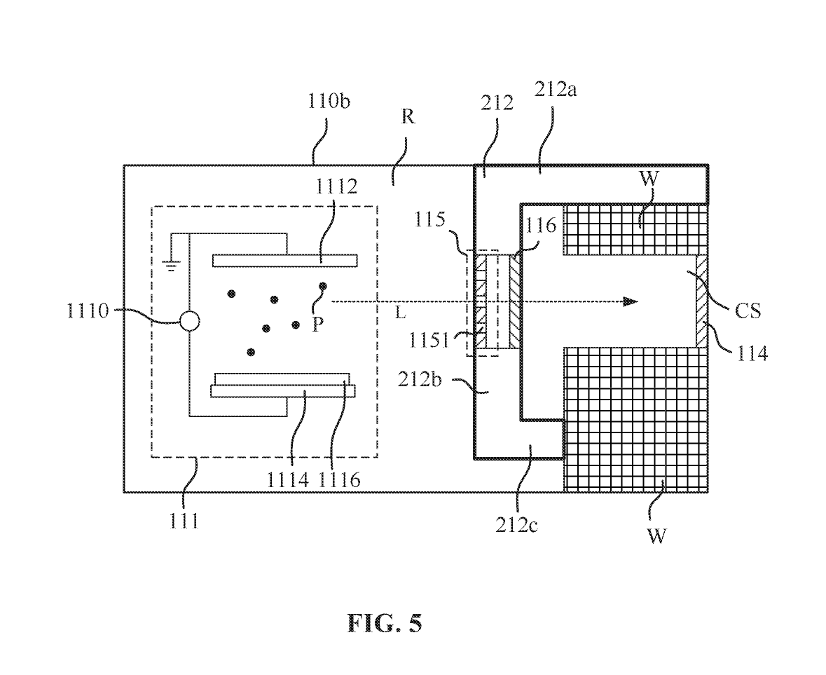

FIG. 5 is a schematic diagram illustrating the chamber 110 of the system 100 in FIG. 1, in accordance with some embodiments of the present disclosure. In some embodiments, the chamber 110 in FIG. 1 is implemented by a chamber 110b in FIG. 5. For ease of understanding, with respect to the embodiments of FIG. 2, like elements in FIG. 5 are designated with the same reference numbers.

The following description is provided for illustrating differences between the chamber 110a in FIG. 2 and the chamber 110b in FIG. 5. As other components in FIG. 5 are similar to the components discussed in the aforementioned embodiments, the detailed descriptions are thus not provided here again. For illustration, the protection device 212 is configured to be installed on the side wall W. The protection device 212 is configured to protect the side wall W and the window 114 from the plasma P.

For illustration, a shape of the protection device 212 in FIG. 5 is different from the protection device 112 in FIG. 2. In some embodiments, the protection device 212 includes a portion 212a, a portion 212b, and a portion 212c. The portion 212b is connected between the portion 212a and the portion 212c, and is arranged with respect to the tool 111 and the window 114. The portion 212a is configured to be installed on the side wall W. The filtering device 115 and the window 116 are configured to be installed on the portion 212b. The portion 212c is in contact with and supported by the side wall W.

As illustratively shown in FIG. 5, the protection device 212, the window 116, the side wall W, and the window 114 form a closed space CS at a side of the tool 111. For illustration, when the window 116 and the protection device 212 are installed, a room R and the closed space CS are formed in the chamber 110b. The tool 111 is disposed in the room R and the room R is excluding from the closed space CS. As the closed space CS is without any entrance accessing to the room R, the byproducts generated in the room R are unable to enter into the closed space CS.

Correspondingly, the byproducts are prevented from being depositing on the window 114. As a result, the transmittance of the window 114 is maintained and the intensity of the light L received by the light receiving device 120 can be kept.

The shape of the protection device 212 is given for illustrative purposes only. Various shapes of the protection device 212 are within the contemplated scope of the present disclosure.

In some embodiments, a system includes a protection device and a blocking device. The protection device is installed on a wall of a chamber. The protection device is configured to protect the wall of the chamber from plasma associated with a semiconductor manufacturing process. The semiconductor manufacturing process is performed by a tool. The blocking device is arranged between the protection device and the wall to block up a gap therebetween.

Also disclosed is a system that includes a first window, a protection device, and a second window. The first window is installed on a wall of a chamber. The protection device is configured to shield the wall. The second window is installed on the protection device. Light is transmitted from the second window to the first window and is associated with a semiconductor manufacturing process. The semiconductor manufacturing process is performed by a tool. The second window, the first window, the protection device, and the wall are arranged to form a closed space at a side of the tool.

Also disclosed is a method that includes the operations below. Light passing through a protection device is guided from a tool to a first window by a blocking device. The light passing through the first window is detected by a sensor, to generate a control signal for controlling a semiconductor manufacturing process associated with the light.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a protection device installed on a wall of a chamber, the protection device configured to protect the wall of the chamber from plasma associated with a semiconductor manufacturing process that is performed by a tool; and
a blocking device arranged between the protection device and the wall to block up a gap therebetween.

2. The system of claim 1, further comprising:
a first window installed on the wall of the chamber; and
a light receiving device configured to receive light passing through a through-hole of the blocking device and the first window,
wherein the light is generated during the semiconductor manufacturing process is performed.

3. The system of claim 2, wherein the through-hole of the blocking device is configured to be a guiding channel for guiding the light from the tool to the first window.

4. The system of claim 2, wherein the light receiving device is aligned in a direction of an axis of the through-hole.

5. The system of claim 2, further comprising:
a second window installed on the protection device,
wherein the light is transmitted to the through-hole of the blocking device via the second window.

6. The system of claim 5, wherein the second window is disposed at a first side of the blocking device, the first window is disposed at a second side of the blocking device, and the first side is opposite to the second side.

7. The system of claim 5, wherein the plasma is generated during the semiconductor manufacturing process is performed, and the second window and the protection device are further configured to protect the first window from the plasma.

8. The system of claim 2, wherein the plasma is generated during the semiconductor manufacturing process is performed, and the system further comprises:
a filtering device disposed on the protection device, the filtering device configured to filter the plasma;
wherein the light receiving device is configured to receive the light via the filtering device.

9. The system of claim 2, further comprising:
a sensor coupled to the light receiving device and configured to generate spectrum information according to the light from the first window.

10. The system of claim 9, further comprising:
a first processing device coupled to the sensor and configured to process the spectrum information to generate analyzed information.

11. The system of claim 10, further comprising:
a second processing device coupled to the first processing device and configured to control the tool according to the analyzed information.

12. A system, comprising:
a first window installed on a wall of a chamber;
a protection device configured to shield the wall; and
a second window installed on the protection device,
wherein light is transmitted from the second window to the first window and is associated with a semiconductor manufacturing process that is performed by a tool, and the second window, the first window, the protection device, and the wall are arranged to form a closed space at a side of the tool.

13. The system of claim 12, wherein plasma is generated during the semiconductor manufacturing process is performed, the first window, the protection device, the second window, and the tool are contained in the chamber, and the closed space is formed to protect the wall of the chamber from the plasma from a room excluding the closed space in the chamber.

14. The system of claim 12, wherein plasma is generated during the semiconductor manufacturing process is performed, and the system further comprises:
a filtering device disposed on the protection device, the filtering device configured to filter the plasma,
wherein the light is transmitted to the second window via the filtering device.

15. The system of claim 12, further comprising:
a light receiving device arranged at a side of the first window, and configured to receive the light transmitted from the first window.

16. The system of claim 15, further comprising:
a sensor coupled to the light receiving device, the sensor configured to generate spectrum information according to the light received by the light receiving device;
a first processing device coupled to the sensor and configured to process the spectrum information to generate analyzed information; and
a second processing device coupled to the first processing device and configured to control the semiconductor manufacturing process according to the analyzed information.

17. The system of claim 16, wherein the tool comprises a radio frequency (RF) generator configured to perform the semiconductor manufacturing process, and the second processing device is further configured to turn off the RF generator according to the analyzed information, in order to stop the semiconductor manufacturing process.

18. A method, comprising:
guiding, by a blocking device, light passing through a protection device from a tool to a first window; and
detecting, by a sensor, the light passing through the first window to generate a control signal for controlling a semiconductor manufacturing process associated with the light.

19. The method of claim 18, wherein the light is transmitted through a filter and a second window arranged on the protection device, and guiding the light comprises:
guiding, by a through-hole of the blocking device, the light passing from the second window to the first window.

20. The method of claim 18, wherein detecting the light comprises:
generating, by the sensor, spectrum information according to the light detected by the sensor; and
processing, by a processing device, the spectrum information to generate the control signal.
